(19) United States
(12) Patent Application Publication
(10) Pub. No.: US 2012/0302045 A1
(43) Pub. Date: Nov. 29, 2012

(54) METHOD FOR PRODUCING MOSAIC DIAMOND

(76) Inventors: Hideaki Yamada, Ikeda-shi (JP); Akiyoshi Chayahara, Ikeda-shi (JP); Yoshiaki Mokuno, Ikeda-shi (JP); Shinichi Shikata, Tsukuba-shi (JP)

(21) Appl. No.: 13/515,991

(22) PCT Filed: Dec. 15, 2010
(86) PCT No.: PCT/JP2010/072539

§ 371 Date: Jun. 14, 2012

(30) Foreign Application Priority Data
Dec. 16, 2009 (JP) 2009-284793

(51) Int. Cl. H01L 21/20

(52) U.S. Cl. 438/478; 257/E21.09

(57) ABSTRACT

The present invention discloses a method for producing a mosaic diamond comprising implanting ions in the vicinity of the surfaces of a plurality of single-crystal diamond substrates arranged in the form of a mosaic, or in the vicinity of the surfaces of mosaic single-crystal diamond substrates whose back surfaces are bonded by a single-crystal diamond layer, so as to form non-diamond layers; growing a single-crystal diamond layer by a vapor-phase synthesis method; and separating the single-crystal diamond layer above the non-diamond layers by etching the non-diamond layers. The method of the present invention prevents the destruction of single-crystal diamond substrates by using a process that is simpler than conventional methods, thus allowing a large quantity of mosaic diamond to be produced in a stable and efficient manner.

### TECHNICAL FIELD

The present invention relates to a method for efficiently producing a mosaic diamond with a simple production process.

### BACKGROUND ART

Diamond, which exhibits outstanding properties as a semiconductor, is a promising material for use in semiconductor devices, such as high-output power devices, high-frequency devices, and photoreceptor devices. In particular, in order to realize the practical use of diamond as a semiconductor material, wafers of single-crystal diamond having a large area and uniform quality are required.

Typical methods heretofore used for growing single-crystal diamond include a high-pressure synthesis method and a vapor-phase synthesis method. Of these methods, the high-pressure synthesis method can produce substrates with an area of only up to about 1×1 cm, and cannot be expected to produce single-crystal substrates with a larger area. Furthermore, single-crystal diamond substrates with an area of about 5×5 mm or more are not readily available, nor is it easy to increase the area of these substrates. In addition, about 13×13 mm is the largest size ever reported for a single-crystal diamond produced by the vapor-phase synthesis method (see Non-patent Literature 1 below), and the maximum size of single-crystal diamond substrates generally available is about up to 8×8 mm. Accordingly, in both the high-pressure synthesis method and vapor-phase synthesis method, the production of a single-crystal diamond substrate that is 1 inch in diameter or larger, which simplifies the device fabrication process, has not been yet realized.

In the vapor-phase synthesis method, a single-crystal diamond having a size of 1 inch was realized by a heteroepitaxial growth method wherein a diamond is grown on a different kind of substrate (see Non-patent Literature 2 below). However, the diamond grown by this method is remarkably inferior in crystallinity compared to a diamond grown on a single-crystal substrate.

For this reason, a method for producing a so-called mosaic diamond has been developed to prepare a single-crystal diamond with a large area. This method involves growing diamond crystals by a vapor-phase method on a plurality of diamond crystals arranged on a support surface, and bonding the arranged diamond crystals, thereby producing a large diamond crystal (see Patent Literature 1 below).

However, the above method requires many substrates synthesized by a high-pressure, high-temperature method in order to produce one large mosaic diamond substrate. Furthermore, in order to reuse the substrate, it is necessary to remove the grown layer from the substrate by means of laser cutting or the like. In this case, particularly when separating a large substrate exceeding 10 mm by laser cutting, a considerably long time is required for cutting, the amount of loss becomes large, and the diamond crystal may be destroyed.

In order to solve these problems, the method described below is proposed (see Patent Literature 2 below), wherein a mosaic diamond substrate is prepared in the same manner as described above, and ions are implanted into the substrate. After growing diamond, the diamond growth layer is separated from the mosaic diamond substrate to produce a mosaic diamond. According to this method, by repeatedly implanting ions to the mosaic diamond substrate and growing diamond thereon, the mosaic diamond can be duplicated. This method requires forming a flat and smooth surface prior to ion implantation, by polishing the surface of the diamonds after growing them on a plurality of diamond seed crystals and bonding them to form a mosaic diamond. However, because precise diamond processing is extremely difficult, a great deal of time is required when the area of the bonded substrate increases, and the diamond crystal may be destroyed when polished.

### CITATION LIST

### Patent Literature

PTL 1: Japanese Unexamined Patent Publication No. H7-48198
PTL 2: Japanese Unexamined Patent Publication No. 2009-502705

### NON-PATENT LITERATURE

### Non-patent Literature

NPL 1: Y. Mokuno, A. Chayahara, H. Yamada, and N. Tsubouchi, Diamond and Related Materials 18, 1258 (2009).
NPL 2: Maeda, Watanabe, Ando, Suzuki, Sawabe, The 19^{th} Diamond Symposium, Summary, 50 (2005).

### SUMMARY OF INVENTION

### Technical Problem

The present invention was made in view of the current condition of the conventional techniques. A major object of the present invention is to provide a method for efficiently producing a large quantity of mosaic diamond with a high yield by preventing the destruction of single-crystal diamond substrates using a simpler production method compared to conventional methods.

### Solution to Problem

The present inventors have conducted extensive research to achieve the above object. As a result, they found that a large mosaic diamond can be obtained effectively by an easy process without the complicated step of mechanically polishing the diamond layer. The method comprises the steps of implanting ions into a plurality of single-crystal diamond substrates, which serve as seed substrates, to form non-diamond layers in the vicinity of the surfaces of the single-crystal diamond substrates; arranging the single-crystal diamond substrates into a mosaic pattern on a flat support before or after ion implantation; forming a single-crystal diamond layer on the surfaces of the ion-implanted single-crystal diamond substrates by a vapor-phase synthesis method to bond the plurality of single-crystal diamond substrates; and, subsequently, etching the non-diamond layers to separate the single-crystal diamond layer formed in the portion above the non-diamond layers. The present inventors also found that the following process makes it possible to produce a large mosaic diamond by an easy process without the complicated step of surface polishing. That is, after implanting ions into a plurality of single-crystal diamond substrates, the single-crystal diamond substrates are inverted and arranged to form a mosaic pattern on a flat support. Subsequently, a single-crystal diamond layer is formed by a vapor-phase synthesis method to bond the plurality of single-crystal diamond substrates, and the bonded single-crystal diamond substrates are again inverted on the support. Alternatively, after bonding the plurality of single-crystal diamond substrates by forming a single-crystal diamond layer by a vapor-phase synthesis method on the surfaces of the single-crystal diamond substrates that were arranged on a flat support to form a mosaic pattern, the bonded single-crystal diamond substrates are inverted on the support and ions are implanted therein. Following either of the above processes, non-diamond layers can be formed in the vicinity of the surfaces of the plurality of single-crystal diamond substrates bonded into a mosaic pattern. Subsequently, a single-crystal diamond layer is formed by a vapor-phase synthesis method on the substrate surface formed by the non-diamond layers, and the non-diamond layers are etched to separate the single-crystal diamond layer located above the non-diamond layers. Furthermore, the present inventors found that, after producing a mosaic diamond by either of the methods described above, repeating the formation of non-diamond layers by implanting ions, and the etching of the non-diamond layers, a large quantity of mosaic diamonds can be easily produced. The invention was accomplished as a result of further extensive research based on these novel findings.

More specifically, the present invention provides a process for producing a mosaic diamond as described below.

Item 1. A process for producing a mosaic diamond comprising:

implanting ions into a plurality of single-crystal diamond substrates to form non-diamond layers in the vicinity of the surfaces of the single-crystal diamond substrates;

arranging the single-crystal diamond substrates to form a mosaic pattern on a flat support before or after ion implantation;

growing a single-crystal diamond layer, by a vapor-phase synthesis method, on the ion-implanted surfaces of the single-crystal diamond substrates, which were arranged to form a mosaic pattern, to bond the single-crystal diamond substrates; and

etching the non-diamond layers to separate the single-crystal diamond layer in the portion above the non-diamond layers.

Item 2. A process for producing a mosaic diamond comprising steps (i) to (v) below:

(i) implanting ions into a plurality of single-crystal diamond substrates to form non-diamond layers in the vicinity of the surfaces of the single-crystal diamond substrates;

(ii) inverting each single-crystal diamond substrate having a non-diamond layer formed thereon and arranging the single-crystal diamond substrates to form a mosaic pattern on a flat support;

(iii) growing a single-crystal diamond layer, by a vapor-phase synthesis method, on the surfaces of the single-crystal diamond substrates, which were arranged to form a mosaic pattern, to bond the single-crystal diamond substrates;

(iv) inverting the bonded single-crystal diamond substrates on the flat support again to make the ion-implanted surfaces face upward and growing a single-crystal diamond layer on the ion-implanted surfaces by a vapor-phase synthesis method; and

(v) after growing the single-crystal diamond layer in (iv), etching the non-diamond layers to separate the single-crystal diamond layer in the portion above the non-diamond layers.

Item 3. A process for producing a mosaic diamond comprising steps (i) to (vi) below:

(i) arranging a plurality of single-crystal diamond substrates on a flat support to form a mosaic pattern;

(ii) growing a single-crystal diamond layer on the surfaces of the single-crystal diamond substrates, which were arranged to form a mosaic pattern, by a vapor-phase synthesis method, to bond the single-crystal diamond substrates;

(iii) inverting the bonded single-crystal diamond substrates on the flat support;

(iv) implanting ions into the inverted single-crystal diamond substrates to form non-diamond layers in the vicinity of the surfaces of the single-crystal diamond substrates;

(v) growing a single-crystal diamond layer by a vapor-phase synthesis method on the surface of each single-crystal diamond substrate having a non-diamond layer formed thereon; and

(vi) after growing the single-crystal diamond layer, etching the non-diamond layers to separate the single-crystal diamond layer in the portion above the non-diamond layers.

Item 4. A process for producing a mosaic diamond by performing the following steps at least one time: separating the single-crystal diamond layer formed in the portion above the non-diamond layers by any process of Items 1 to 3;

implanting ions into the single-crystal diamond substrates, from which the single-crystal diamond layer was separated, to form non-diamond layers in the vicinity of the surfaces of the single-crystal diamond substrates;

growing a single-crystal diamond layer on the surfaces of the substrates by a vapor-phase synthesis method; and

etching the non-diamond layers to separate the single-crystal diamond layer formed in the portion above the non-diamond layers.

Item 5. A process for producing a mosaic diamond by performing the following steps at least one time:

separating the single-crystal diamond layer formed in the portion above the non-diamond layers by any process of Items 1 to 3 to obtain a mosaic diamond;

implanting ions into the separated face of the separated mosaic diamond to form a non-diamond layer in the vicinity of the surface of the mosaic diamond;

growing a single-crystal diamond layer on the surface of the diamond by a vapor-phase synthesis method; and

etching the non-diamond layer to separate the single-crystal diamond layer formed in the portion above the non-diamond layer.

The method of the present invention is explained in detail below.

### Seed Substrate

In the present invention, a single-crystal diamond substrate is used as a seed substrate, which serves as a base for the diamond portion of a mosaic diamond. The type of single-crystal diamond is not limited, and a single-crystal diamond having a crystal face capable of epitaxial growth or one having a surface with an angle of inclination, i.e., an off-angle, with respect to the above-mentioned crystal face may be used. The production method for the single-crystal diamond is also not limited, and, in addition to natural diamonds, synthetic single-crystal diamonds produced by, for example, a high-pressure, high-temperature synthetic method, a vapor-phase synthetic method, or the like may be used.

In particular, in order to grow a semiconductor-grade diamond, generally, a single-crystal diamond having a (100), (111) or like crystal plane, or a single-crystal diamond having an off-angle up to about 10° relative to the aforementioned crystal planes may be used.

In the present invention, by using a plurality of single-crystal diamond substrates separated from an identical single-crystal diamond substrate as seed substrates, the off-angle, crystal plane direction, strain distribution and defect distribution in the plurality of seed substrates can be made uniform. This allows the mosaic diamond ultimately obtained to have a uniform off-angle, crystal plane direction, strain distribution, defect distribution, etc. In this case, a method for separating a plurality of single-crystal diamond substrates from an identical single-crystal diamond substrate may comprise forming a non-diamond layer in the vicinity of the surface of each single-crystal diamond substrate by implanting ions, etching the resulting non-diamond layer to separate the surface layer, and repeating these steps a number of times. The conditions for implanting ions and etching the non-diamond layer may be the same as those in the methods described below.

### Mosaic Diamond Production Method

### (1) First Method:

FIG. 1 shows a conceptual diagram illustrating one example of a method for producing the mosaic diamond of the present invention. In the method shown in FIG. 1, first, ions are implanted into a plurality of single-crystal diamond substrates, which serve as seed substrates, to form non-diamond layers in the vicinity of the surfaces of the single-crystal diamond substrates. The single-crystal diamond substrates, which serve as seed substrates, are arranged into a mosaic pattern on a flat support before or after ion implantation. A single-crystal diamond layer is grown on the surfaces of the ion-implanted single-crystal diamond substrates by a vapor-phase synthesis method to bond the single-crystal diamond substrates arranged into a mosaic pattern. Thereafter, the non-diamond layers are etched to separate the single-crystal diamond layer formed in the portion above the non-diamond layers, and a mosaic diamond is thereby obtained (hereunder, this method is referred to as “the first method of the present invention”).

Each step of the first method of the present invention is explained in detail below.

### (i) Ion Implantation Step

In the first method of the present invention, ions are first implanted into a plurality of single-crystal diamond substrates, which serve as seed substrates, to form ion-implanted layers whose crystal structure is deteriorated in the vicinity of the surfaces of the substrates.

The ion implantation method is a method in which a sample is irradiated with swift ions. In general, ions are implanted as follows: a desired element is ionized and extracted. The resulting ions are accelerated in an electric field created by applying a voltage, after which the ions are mass-separated, and ions with a desired level of energy are directed to the sample. Alternatively, this may be performed by a plasma-ion implantation method, in which the sample is immersed in a plasma, and negative high-voltage pulses are applied to the sample to attract the positive ions in the plasma to the sample. Examples of implanted ions include carbon, oxygen, argon, helium, protons and the like.

The ion implantation energy may be in the range of about 10 keV to 10 MeV, which is typically used in ion implantation. The implanted ions are distributed mainly at an implantation depth (projectile range) having a certain span, that is determined according to the type and energy of the ions, as well as the type of sample. Damage to the sample is greatest in the vicinity of the projectile range where the ions stop, but the surface side of the substrate above the vicinity of the projectile range also experiences a certain degree of damage caused by the passage of the ions. The projectile range and the degree of damage can be calculated and predicted using a Monte Carlo simulation code, such as the SRIM code, which can be downloaded from, for example, http://www.srim.org/index.htm#HOMETOP (The Stopping and Range of Ions in Matter, James F. Ziegler, Jochen P. Biersack, Matthias D. Ziegler).

By implanting ions into the single-crystal diamond substrate, the crystal structure at the surface side of the substrate above the vicinity of the projectile range deteriorates when the dose exceeds a certain level, destroying the diamond structure and forming a non-diamond layer.

The depth and thickness of the resulting non-diamond layer vary depending on the type of ions used, the ion implantation energy, the dose, the type of material into which the ions are implanted, and the like. Therefore, these conditions may be determined so that a separable non-diamond layer is formed in the vicinity of the projectile range. Generally, the maximum atomic density of the implanted ions is preferably about 1×10²⁰ atoms/cm³ or more; and, in order to ensure the formation of a non-diamond layer, the maximum atomic density is preferably about 1×10²¹ atoms/cm³ or more.

For example, when carbon ions are implanted at an implantation energy of 3 MeV, the ion dose may be from about 1×10¹⁶ to 1×10¹⁷ ions/cm². In this case, if the ion dose is too high, the crystallinity of the surface deteriorates, whereas if the dose is too low, a non-diamond layer is not sufficiently formed, making it difficult to separate the surface layer portion.

By implanting ions according to the above-described method, a non-diamond layer can be formed in the vicinity of the surface of the seed substrate.

In the invention, the depth at which the non-diamond layer is formed is not limited; however, the greater the depth, the thicker the mosaic diamond that can be subsequently separated.

After the ions are implanted, a heat treatment is conducted on the parent substrate at a temperature of 600° C. or higher in a non-oxidizing atmosphere, such as a vacuum, a reducing atmosphere, or an oxygen-free inert gas atmosphere, thereby allowing graphitization of the non-diamond layer to proceed. This causes the etching in the subsequent step to proceed more rapidly. The upper limit for the heat-treatment temperature is the temperature at which the diamond begins to graphitize, which is typically about 1,200° C. The heat-treatment time varies depending on the treatment conditions, such as the heat-treatment temperature and the like; for example, it may be about 5 minutes to 10 hours.

When implanting ions, there is no limitation on the way of arranging the single-crystal diamond substrates, which serve as seed substrates, and they may be arbitrarily arranged within a range that allows the ions to be implanted uniformly thereon. However, the single-crystal diamond substrates, which serve as seed substrates, must be arranged to form a mosaic pattern on a flat support before growing a single-crystal diamond in the single-crystal diamond growing process described below. Therefore, it is necessary that the single-crystal diamond substrates be arranged to form a mosaic pattern on a flat support before or after ion implantation.

There is no limitation on how arranging the single-crystal diamond substrates to form a mosaic pattern, and usually they may be arranged in such a manner that the side faces of each substrate are in contact with each other or the distances between the side faces become as small as possible so that an objective mosaic pattern can be formed on a flat support. In this case, when a plurality of single-crystal diamond substrates separated from an identical single-crystal diamond substrate are used as seed substrates, by arranging them so that they have the same crystal face direction, a mosaic diamond having a uniform off-angle, crystal face direction, strain distribution, defect distribution, etc., can be obtained.

When substrates are arranged to form a mosaic pattern, abnormal diamond growth tends to easily occur in the portion where the vertexes of the substrates come close. Therefore, when three or more substrates are arranged, it is preferable to prevent the vertexes of the three or more substrates from contacting each other or coming close to each other. Specifically, when two substrates are arranged in such a manner that their vertexes are in contact with or come close to each other, it is desirable that the substrates be arranged in such a manner that the vertexes of other substrates are shifted from the portion where the vertexes of the two substrates are in contact with or come close to each other.

The single-crystal diamond substrates are preferably arranged so that the side faces, where the substrates contact each other when arranged to form a mosaic pattern, and the surfaces of the substrates form an angle of 90° or less, and the angle (edge) formed between the side faces and the surfaces of the substrates be about 90° or less or be a curved surface having a radius of curvature as small as possible. This narrows the interval W between the edges of adjacent substrate surfaces. Therefore, when a single-crystal diamond layer is formed thereon by a vapor-phase synthesis method, the region in the grown diamond layer that has inferior crystallinity can be narrowed.

FIG. 2 schematically shows such a condition. In FIG. 2, the upper left figure is an enlarged view of the edge portions when two substrates each having an edge portion with a large radius of curvature are arranged, and the lower left figure is an enlarged view of the edge portions when two substrates each having an edge portion with about 90° are arranged.

In this case, it is preferable that the edge portion along the ridgeline formed by the side face and the substrate surface be processed as precisely as possible to make the edge portion almost a straight line. For example, as shown in FIG. 2, when the interval between the edge portions of two adjacent substrates is defined as W, the maximum width E of the shift from the straight line of the edge portion is such that the value E/W becomes preferably about 1/10 or less, and more preferably about 10⁻⁶ or less.

In FIG. 2, the lower left figure shows the condition where the edge portion of a substrate has a small shift from the straight line and the interval W between the edge portions of two adjacent substrates is narrow. As is clear from the comparison between the upper right figure and the lower right figure of FIG. 2, when a single-crystal diamond layer is grown by a vapor-phase synthesis method on arranged substrates each having an edge portion with an angle of about 90° and little shift from the straight line, the region in which a diamond layer having inferior crystallinity is formed can be made very narrow. This makes it possible to widen the area in which a single-crystal diamond layer with high quality is formed.

The method for processing the side faces of single-crystal diamond substrates so as to satisfy the above conditions is not limited and known methods are applicable, such as, scaife polishing, mechanochemical polishing, laser processing, ultraviolet irradiation, plasma etching, ion beam etching, and neutral beam irradiation. The higher the processing accuracy, the more preferable. Examples of applicable methods include polishing using fine metal particles, hydrogen peroxide and the like as an abrasive; laser processing using laser light having a short pulse width and short wavelength; ultraviolet irradiation using a stepper and the like; plasma etching using a lithographic technique; ion beam etching; neutral beam irradiation; and the like.

The shapes of the side faces and edge portions of the single-crystal diamond substrates described above are also applicable to the single-crystal diamond substrates of the second and third methods of the present invention described below.

The type of support is not limited as long as it has a flat portion on which all of the single-crystal diamond substrates, which serve as seed substrates, can be arranged. When the support used in ion implantation is also used in the growing process of single-crystal diamond by the vapor-phase synthesis method described below, it is desirable to use a support formed of a metal or an alloy with a high-melting point and excellent thermal conductivity suitable for the vapor-phase synthesis method, such as molybdenum or tungsten.

### (ii) Single-Crystal Diamond Growing Process:

Subsequently, non-diamond layers are formed by the method described above, and a single-crystal diamond is formed by a vapor-phase synthesis method on the surfaces of the seed substrates arranged to form a mosaic pattern.

The vapor-phase synthesis method is not limited, and known methods, such as a microwave plasma CVD method, a hot filament method, and a DC discharge method, are applicable.

A high-purity diamond single-crystal film can be grown by using, in particular, a microwave plasma CVD method. Specific production conditions are not limited; a single-crystal diamond may be grown according to known conditions. For example, a gas mixture of methane and hydrogen can be used as a source gas. Specifically, the conditions for diamond growth may, for example, be as follows. When a gas mixture of hydrogen and methane is used as a reaction gas, methane is preferably supplied in a proportion of about 0.01 to 0.33 mol per mol of hydrogen supplied. The pressure inside the plasma CVD apparatus can be typically about 13.3 to 40 kPa. Microwaves typically used are those having a frequency of 2.45 GHz, 915 MHz, or like frequencies that are industrially or scientifically permitted. The microwave power is not limited, and is typically about 0.5 to 5 kW. Within these ranges, the conditions may be adjusted so that the temperature of the single-crystal diamond substrate is about 900 to 1,300° C. and preferably about 900 to 1,100° C.

The thickness of the grown single-crystal diamond is not limited and can be suitably selected depending on the thickness of the objective mosaic diamond. For example, the thickness thereof may be about 100 to 1,000 μm.

(iii) Step of Etching the Non-Diamond Layers:

After growing the single-crystal diamond layer by the method described above, the diamond layer in the surface portion above the non-diamond layers is separated by etching the non-diamond layers that were formed in Step (i). This causes the single-crystal diamond at the surface portion to be separated and an objective mosaic diamond to be obtained. This method eliminates the need for the troublesome step of cutting and polishing the grown diamond layer, simplifies the production process, and prevents damage to the diamond crystal caused by polishing.

In contrast, for example, in the method disclosed in Patent Literature 2 mentioned above, it is necessary to polish the surface of the grown diamond to form a flat surface after forming a mosaic diamond by growing a diamond on a plurality of diamonds, which serve as seed crystals, and before implanting ions. In such a case, in addition to the fact that bonded mosaic diamonds are apt to easily break during the polishing step, the polishing step requires a great deal of time to polish a mosaic diamond that has been enlarged by bonding.

However, in the present invention, the troublesome step of cutting and polishing the grown diamond layer is unnecessary. This greatly reduces the processing time and remarkably improves the production efficiency because it enhances the yield.

The method for separating the surface portion from the non-diamond layers is not limited; for example, methods such as electrochemical etching, thermal oxidation, electrical discharge machining, etc., can be applied.

An example of the method for removing the non-diamond layer by electrochemical etching is as follows. Two electrodes are disposed at a certain interval in an electrolytic solution. A single-crystal diamond in which a non-diamond layer has been formed is placed between the electrodes in the electrolytic solution, and a DC voltage is applied across the electrodes. The electrolytic solution is preferably pure water. The electrode material may be any conductive material, and, in particular, chemically stable electrodes, such as platinum, graphite and the like, are preferred. The electrode interval and the applied voltage may be adjusted to allow the etching to proceed most rapidly. The electric field strength in the electrolytic solution is typically from about 100 to 300 V/cm.

Moreover, when etching is conducted by applying an AC voltage in the method for removing the non-diamond layer by electrochemical etching, even if many single-crystal diamond substrates are arranged in a mosaic pattern, etching proceeds extremely rapidly into the non-diamond layers, allowing the diamond to be separated at the surface portion above the non-diamond layers in a short period of time.

Also in the method wherein an AC voltage is applied, the electrode interval and the applied voltage may be adjusted so that the etching proceeds most rapidly. Typically, the electric field strength in the electrolytic solution, which is determined by dividing the applied voltage by the electrode interval, is preferably about 50 to 10,000 V/cm, and more preferably about 500 to 10,000 V/cm.

While a commercial sinusoidal alternating current with a frequency of 60 or 50 Hz is readily available as an alternating current, the waveform may be one other than a sinusoidal wave, as long as the current has a similar frequency component.

It is advantageous for the pure water that is used as an electrolytic solution to have high resistivity (i.e., low conductivity) to allow the application of a higher voltage. Ultrapure water produced using a general apparatus for producing ultrapure water has sufficiently high resistivity, i.e., about 18 MΩ·cm, and is thus suitable for use as an electrolytic solution.

An example of the method for removing the non-diamond layer by thermal oxidation is as follows. The substrate is heated to a high temperature of about 500 to 900° C. in an oxygen atmosphere, thereby etching the non-diamond layer by oxidation. In this method, as etching proceeds farther into the diamond, the passage of oxygen from the outer periphery of the crystal becomes difficult. For this reason, if oxygen ions have been selected as the ions for forming a non-diamond layer, and implanted at a dose sufficiently greater than the dose necessary for etching to occur, oxygen can also be supplied from the inside of the non-diamond layer during etching, allowing the non-diamond layer to be etched more rapidly.

Because the graphitized non-diamond layer is electrically conductive, it can also be cut (etched) by electrical discharge machining.

By etching the non-diamond layer by the method described above to separate the single-crystal diamond layer in the surface portion above the non-diamond layer, an objective mosaic diamond can be obtained.

A plurality of mosaic diamonds can also be easily produced, after separating the mosaic diamond by the method described above, by repeating the steps of implanting ions into a plurality of single-crystal diamond substrates arranged to form a mosaic pattern, growing single-crystal diamond by a vapor-phase synthesis method, and etching the non-diamond layers.

### (2) Second Method:

FIG. 3 shows a conceptual diagram of another example of a method for producing the mosaic diamond method of the present invention. The method shown in FIG. 3 includes the steps (i) to (v) described below (hereunder, this method is referred to as “the second method of the present invention”):

(i) implanting ions into a plurality of single-crystal diamond substrates, which serve as seed crystals, to form non-diamond layers in the vicinity of the surfaces of the single-crystal diamond substrates;

(ii) inverting each single-crystal diamond substrate having a non-diamond layer formed thereon and arranging the single-crystal diamond substrates to form a mosaic pattern on a flat support;

(iii) growing a single-crystal diamond layer on the single-crystal diamond substrates, which were arranged to form a mosaic pattern in Step (ii), by a vapor-phase synthesis method, to bond the single-crystal diamond substrates;

(iv) inverting the bonded single-crystal diamond substrates on the flat support again to make the ion-implanted surfaces face upward, and growing a single-crystal diamond layer on the ion-implanted surfaces by a vapor-phase synthesis method; and

(v) after growing the single-crystal diamond layer, etching the non-diamond layers to separate the single-crystal diamond layer formed in the portion above the non-diamond layers.

In the second method of the present invention, in Step (i) described above, ions are implanted into the single-crystal diamond substrates, which serve as seed substrates, to form non-diamond layers. Here, there is no limitation on arranging the single-crystal diamond substrates and they may be arbitrarily arranged within a range that allows ions to be implanted uniformly therein. The conditions for the ion implantation may be the same as those employed in the first method of the present invention.

In Step (ii) of the second method of the present invention, each single-crystal diamond substrate having a non-diamond layer formed thereon in Step (i) by ion implantation is inverted and arranged on a flat support to form a mosaic pattern. Here, the surfaces of the single-crystal diamond substrates in which ions were implanted are placed in contact with the support.

In Step (iii), a single-crystal diamond layer is grown by a vapor-phase synthesis method on the surfaces opposite to the ion-implanted surfaces of the single-crystal diamond substrates that were arranged to form a mosaic pattern, thereby bonding the plurality of single-crystal diamond substrates. This bonding step makes it possible to obtain mosaic substrates having substantially the same height for the surfaces that underwent ion implantation, without having to strictly unify the thicknesses of the seed substrates.

The method for growing the single-crystal diamond layer is not limited and, for example, the conditions thereof may be the same as those employed in the single-crystal diamond growing process of the first method of the present invention. The thickness of the formed single-crystal diamond layer is not limited as long as it can impart sufficient bonding strength to each single-crystal diamond substrate, and, for example, can be about 100 to 1,000 μm. Furthermore, this bonding step thermally bonds each of the single-crystal substrates. This unifies the temperature distribution of the substrate in the subsequent Step (iv); therefore, the effect of obtaining a uniform distribution of the growth parameters, such as the growth rate, can be expected.

In Step (iv), the single-crystal diamond substrates bonded in Step (iii) are inverted on the flat support again with the ion-implanted surfaces facing upward, and a single-crystal diamond layer is grown on the ion-implanted surfaces by a vapor-phase synthesis method. The conditions for growing the single-crystal diamond may also be the same as those employed in the first method of the present invention. The thickness of the formed single-crystal diamond layer may be suitably selected depending on the thickness of the objective mosaic diamond, and the thickness may be, for example, about 100 to 1,000 μm.

Subsequently, in Step (v), the non-diamond layers are etched to separate the single-crystal diamond layer formed in the portion above the non-diamond layers. This causes the single-crystal diamond at the surface portion to be separated and an objective mosaic diamond to be obtained. This method also eliminates the need for the troublesome step of cutting and polishing the grown diamond layer, simplifies the production process, and prevents damage to the diamond crystal during polishing.

After separating the mosaic diamond by the method described above, a plurality of mosaic diamonds can be easily produced by repeatedly performing the following steps to a plurality of single-crystal diamond substrates from which a mosaic diamond was separated. That is, forming non-diamond layers by ion implantation, growing a single-crystal diamond by a vapor-phase synthesis method, and etching the non-diamond layers.

### (3) Third Method:

Still another example of a method for producing the mosaic diamond of the present invention includes Steps (i) to (vi) described below (hereunder, this method is referred to as “the third method of the present invention”):

(i) arranging a plurality of single-crystal diamond substrates on a flat support to form a mosaic pattern;

(ii) growing a single-crystal diamond layer on the surfaces of the single-crystal diamond substrates, which were arranged to form a mosaic pattern, by a vapor-phase synthesis method, to bond the single-crystal diamond substrates;

(iii) inverting the bonded single-crystal diamond substrates on the flat support;

(iv) implanting ions on the inverted single-crystal diamond substrates to form non-diamond layers in the vicinity of the surfaces of the single-crystal diamond substrates;

(v) growing a single-crystal diamond layer by a vapor-phase synthesis method on the surface of each single-crystal diamond substrate having a non-diamond layer formed thereon; and

(vi) after growing the single-crystal diamond layer, etching the non-diamond layers to separate the single-crystal diamond layer formed in the portion above the non-diamond layers.

In the third method of the present invention, a plurality of single-crystal diamond substrates, which serve as seed substrates, are arranged on a flat support to form a mosaic pattern in Step (i). The method thereof is not limited and the single-crystal diamond substrates may be arranged in the same manner as the seed substrates are arranged in the first method of the present invention.

In Step (ii), a single-crystal diamond layer is formed by a vapor-phase synthesis method on the surfaces of the single-crystal diamond substrates arranged to form a mosaic pattern, thereby bonding the single-crystal diamond substrates arranged in a mosaic pattern. In this step, a single-crystal diamond layer may be grown in the same manner as in Step (iii) of the second method of the present invention so that it has sufficient strength to bond each of the single-crystal diamond substrates.

In Step (iii), the bonded single-crystal diamond substrates are inverted on the flat support. This step places the single-crystal diamond layer grown in Step (ii) in contact with the surface of the support.

In Step (iv), ions are implanted into the single-crystal diamond substrates that were inverted in Step (iii) to form non-diamond layers in the vicinity of the surfaces of the single-crystal diamond substrates. The conditions for implanting ions in this step may be the same as those used for implanting ions in the first method of the present invention.

Subsequently, in Step (v), a single-crystal diamond layer is grown by a vapor-phase synthesis method on the surface of each single-crystal diamond substrate having a non-diamond layer formed thereon. Thereafter, in Step (vi), the non-diamond layers are etched to separate the single-crystal diamond layer at the surfaces above the non-diamond layers. This causes the single-crystal diamond at the surface portion to be separated and an objective mosaic diamond to be obtained. The conditions of Steps (v) and (vi) may be the same as those in Steps (iv) and (v) of the second method of the present invention. This method also eliminates the need for the troublesome step of cutting and polishing the grown diamond layer, simplifies the production process, and prevents damage to the diamond crystal caused by polishing.

A plurality of mosaic diamonds can also be easily produced by repeatedly subjecting the single-crystal diamond substrates from which the mosaic diamond was separated to aforesaid Steps (iv) to (vi), after separating the mosaic diamond by the method described above. Specifically, Steps (iv) to (vi) are: implanting ions to form non-diamond layers, growing a single-crystal diamond by a vapor-phase synthesis method, and etching the non-diamond layers.

Furthermore, in each of the first to third methods of the present invention, a mosaic diamond having the same shape as the original mosaic diamond can be readily obtained by performing the following steps at least one time on the separated faces of the mosaic diamonds that were separated from the seed substrates arranged to form a mosaic pattern:

implanting ions to form non-diamond layers; growing a single-crystal diamond by a vapor-phase synthesis method; and separating the single-crystal diamond layer at the portion above the non-diamond layers by etching the non-diamond layers.

Note that the present invention is applicable to a process for mass-producing single-crystal diamond substrates by employing the following conditions for growing a single-crystal diamond layer in Step (iv) of the second method and Step (v) of the third method, i.e., the steps of growing a single-crystal diamond layer by a vapor-phase synthesis method. That is, the single-crystal diamond layer is grown only on the surface of each seed substrate without reaching the boundary portion between the adjacent seed substrates that are arranged to form a mosaic pattern.

### Advantageous Effects of Invention

The method for producing a mosaic diamond of the present invention allows mosaic diamonds to be produced stably and in a large quantity by a simple process without a complicated step, such as mechanically cutting or polishing the grown diamond crystal.

### BRIEF DESCRIPTION OF DRAWINGS

FIG. 1 is a schematic diagram showing the production process according to the first method of the present invention.

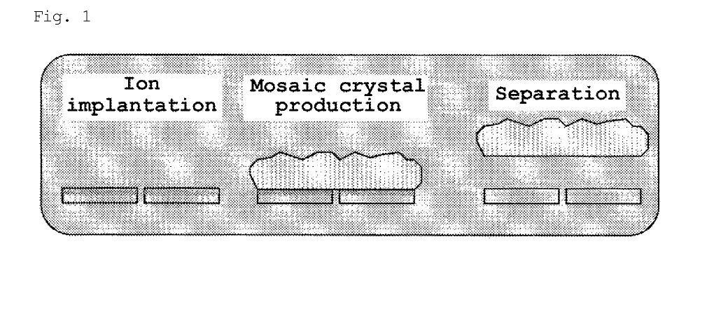

FIG. 2 is a diagram schematically showing the relationship between the side faces and the shape of the edges of a single-crystal diamond substrate and the conditions of a grown diamond layer.

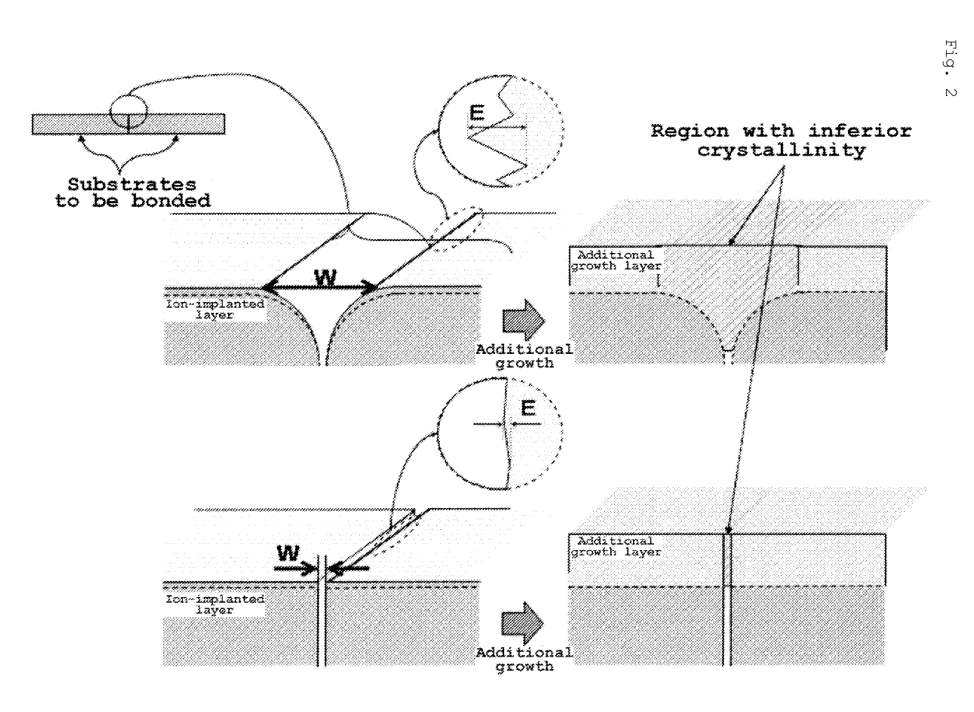

FIG. 3 is a schematic diagram showing the production process according to the second method of the present invention.

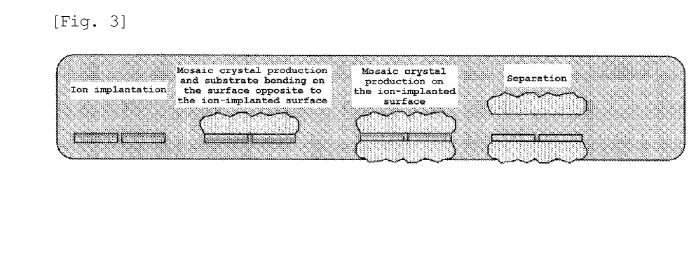

FIG. 4 is a schematic diagram showing the production process according to Example 1.

FIG. 5 is a schematic diagram showing the production process according to Example 2.

### DESCRIPTION OF EMBODIMENTS

The invention is described in greater detail below with reference to the Examples.

### Example 1

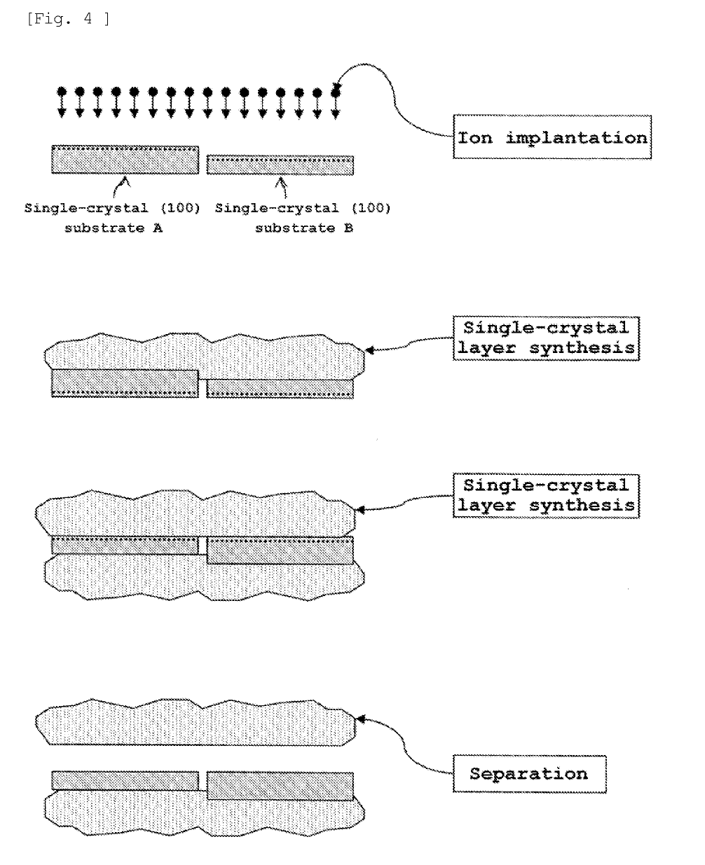

Two single-crystal diamond substrates, i.e., a single-crystal diamond (100) substrate with a size of 4.5×4.5 mm and a thickness of 339 μm, and a single-crystal diamond (100) substrate with a size of 4.5×4.5 mm and a thickness of 212 μm, were used as seed substrates, and a mosaic diamond was produced in the manner shown in FIG. 4.

First, the two aforementioned seed substrates were placed on an aluminum support, and carbon ions were implanted into the seed substrates at an implantation energy of 3 MeV and a dose of 2×10¹⁶ ions/cm², using a 1.5-MV tandem accelerator. The calculated value of the ion implantation depth was about 1.6 μm. As a result of this irradiation, the color of the two diamond substrates changed from transparent to black; this confirmed that non-diamond layers had been formed.

Next, the two ion-implanted seed substrates were inverted on a flat supporting surface of a molybdenum support so that the ion-implanted faces came into contact with the support and the side faces of the seed substrates came into contact with each other.

Subsequently, using a commercially available microwave plasma CVD apparatus, a single-crystal diamond film was grown on the seed substrates for 8 hours under the conditions of a microwave power of 3.5 kW, a gas pressure of 15 kPa, a hydrogen gas flow rate of 500 sccm, and a methane flow rate of 25 sccm. The substrate temperature when the growth was completed was 1,085° C., and the thickness of the formed single-crystal diamond film was 182 μm.

Thereafter, the single-crystal diamond substrates on which a single-crystal diamond film had been formed were inverted on the supporting surface of the molybdenum support so that the grown single-crystal diamond film was in contact with the supporting surface.

Subsequently, using a commercially available microwave plasma CVD apparatus, a single-crystal diamond film was grown on the ion-implanted surfaces of the seed substrates for 7 hours under the conditions of a microwave power of 3.5 kW, a gas pressure of 15 kPa, a hydrogen gas flow rate of 500 sccm, and a methane flow rate of 25 sccm. The substrate temperature when the growth was completed was 1,085° C., and the thickness of the formed single-crystal diamond film was 136 μm.

Two separate platinum electrodes were disposed at an interval of about 1 cm in a beaker containing pure water, and the single-crystal diamond substrates having the single-crystal diamond film grown by the above-described method were placed between the electrodes. An AC voltage with an effective value of 5.6 kV and a frequency of 60 Hz was applied across the electrodes, and the substrates were allowed to stand for 48 hours. As a result, the diamond film formed by the CVD method was separated from the single-crystal diamond substrates and a mosaic diamond was obtained.

### Example 2

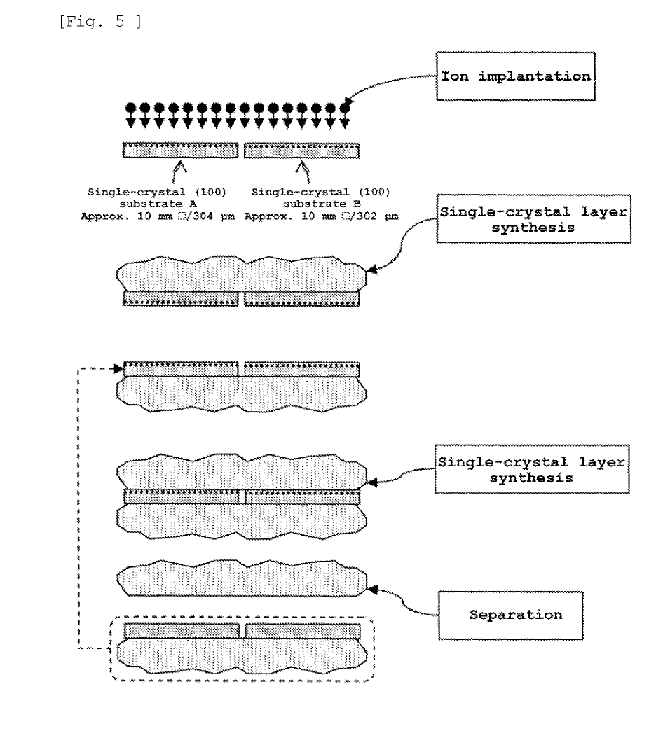

Two single-crystal diamond substrates, i.e., a single-crystal diamond (100) substrate with a size of 10×10 mm and a thickness of 304 μm, and a single-crystal diamond (100) substrate with a size of 10×10 mm and a thickness of 302 μm, were used as seed substrates, and a mosaic diamond was produced in the manner shown in FIG. 5.

First, the two aforementioned seed substrates were placed on an aluminum support, and carbon ions were implanted into the seed substrates at an implantation energy of 3 MeV and a dose of 2×10¹⁶ ions/cm², using a 1.5-MV tandem accelerator. The calculated value of the ion implantation depth was about 1.6 μm. As a result of this irradiation, the color of the two diamond substrates changed from transparent to black; this confirmed that non-diamond layers had been formed.

Next, the two ion-implanted seed substrates were inverted on a flat supporting surface of a molybdenum support so that the ion-implanted faces came into contact with the support and the side faces of the seed substrates came into contact with each other.

Subsequently, using a commercially available microwave plasma CVD apparatus, a single-crystal diamond film was grown on the seed substrates under the conditions of a microwave power of 3.5 kW, a gas pressure of 15 kPa, a hydrogen gas flow rate of 500 sccm, and a methane flow rate of 25 sccm. Growth of the single-crystal diamond film was performed in four steps and the total growth time was 32 hours and 30 minutes. The substrate temperature when the four growth steps were completed was in the range of 1,043 to 1,063° C., and the total thickness of the formed single-crystal diamond film was 322 μm.

Thereafter, the single-crystal diamond substrates on which a single-crystal diamond film was formed were inverted on the supporting surface of the molybdenum support so that the grown single-crystal diamond film was in contact with the supporting surface.

Subsequently, using a commercially available microwave plasma CVD apparatus, a single-crystal diamond film was grown on the ion-implanted surfaces of the seed substrates for 24 hours under the conditions of a microwave power of 4.5 kW, a gas pressure of 17 kPa, a hydrogen gas flow rate of 500 sccm, and a methane flow rate of 25 sccm. The substrate temperature when the growth was completed was 1,105° C., and the thickness of the formed single-crystal diamond film was 437 μm.

Two separate platinum electrodes were disposed at an interval of about 1 cm in a beaker containing pure water, and the single-crystal diamond substrates having the single-crystal diamond film grown by the above-described method were placed between the electrodes. An AC voltage with an effective value of 5.6 kV and a frequency of 60 Hz was applied across the electrodes, and the substrates were allowed to stand for 8 hours. As a result, the diamond film formed by the CVD method was separated from the single-crystal diamond substrates and a mosaic diamond was obtained.

To the single-crystal diamond substrates that resulted from separating the mosaic diamond by the process described above, ions were implanted under the conditions described above into the surfaces from which the mosaic diamond was separated. Subsequently, using a commercially available microwave plasma CVD apparatus, a single-crystal diamond film was grown on the ion-implanted surfaces for 24 hours under the conditions of a microwave power of 4.5 kW, a gas pressure of 16 kPa, a hydrogen gas flow rate of 500 sccm, and a methane flow rate of 25 sccm. The substrate temperature when the growth was completed was 1,090° C., and the thickness of the formed single-crystal diamond film was 462 μm.

From the single-crystal diamond substrates having the single-crystal diamond film grown by the above-described method, non-diamond layers were removed in the same manner as explained above, i.e., performing electrochemical etching in a beaker containing pure water by applying an AC voltage with an effective value of 5.6 kV and a frequency of 60 Hz. As a result, the diamond film formed by the CVD method was separated from the single-crystal diamond substrates and a mosaic diamond was obtained.

1. A process for producing a mosaic diamond comprising:
implanting ions into a plurality of single-crystal diamond substrates to form non-diamond layers in the vicinity of the surfaces of the single-crystal diamond substrates;
arranging the single-crystal diamond substrates to form a mosaic pattern on a flat support before or after ion implantation;
growing a single-crystal diamond layer, by a vapor-phase synthesis method, on the ion-implanted surfaces of the single-crystal diamond substrates, which were arranged to form a mosaic pattern, to bond the single-crystal diamond substrates; and
etching the non-diamond layers to separate the single-crystal diamond layer in the portion above the non-diamond layers.

2. A process for producing a mosaic diamond comprising steps (i) to (v) below:
(i) implanting ions into a plurality of single-crystal diamond substrates to form non-diamond layers in the vicinity of the surfaces of the single-crystal diamond substrates;
(ii) inverting each single-crystal diamond substrate having a non-diamond layer formed thereon and arranging the single-crystal diamond substrates to form a mosaic pattern on a flat support;
(iii) growing a single-crystal diamond layer, by a vapor-phase synthesis method, on the surfaces of the single-crystal diamond substrates, which were arranged to form a mosaic pattern, to bond the single-crystal diamond substrates;
(iv) inverting the bonded single-crystal diamond substrates on the flat support again to make the ion-implanted surfaces face upward and growing a single-crystal diamond layer on the ion-implanted surfaces by a vapor-phase synthesis method; and
(v) after growing the single-crystal diamond layer in (iv), etching the non-diamond layers to separate the single-crystal diamond layer in the portion above the non-diamond layers.

3. A process for producing a mosaic diamond comprising steps (i) to (vi) below:
(i) arranging a plurality of single-crystal diamond substrates on a flat support to form a mosaic pattern;
(ii) growing a single-crystal diamond layer on the surfaces of the single-crystal diamond substrates, which were arranged to form a mosaic pattern, by a vapor-phase synthesis method, to bond the single-crystal diamond substrates;
(iii) inverting the bonded single-crystal diamond substrates on the flat support;
(iv) implanting ions into the inverted single-crystal diamond substrates to form non-diamond layers in the vicinity of the surfaces of the single-crystal diamond substrates;
(v) growing a single-crystal diamond layer by a vapor-phase synthesis method on the surface of each single-crystal diamond substrate having a non-diamond layer formed thereon; and
(vi) after growing the single-crystal diamond layer, etching the non-diamond layers to separate the single-crystal diamond layer in the portion above the non-diamond layers.

4. A process for producing a mosaic diamond by performing the following steps at least one time:
separating the single-crystal diamond layer formed in the portion above the non-diamond layers by any process of claim 1;
implanting ions into the single-crystal diamond substrates, from which the single-crystal diamond layer was separated, to form non-diamond layers in the vicinity of the surfaces of the single-crystal diamond substrates;
growing a single-crystal diamond layer on the surfaces of the substrates by a vapor-phase synthesis method; and
etching the non-diamond layers to separate the single-crystal diamond layer formed in the portion above the non-diamond layers.

5. A process for producing a mosaic diamond by performing the following steps at least one time:
separating the single-crystal diamond layer formed in the portion above the non-diamond layers by any process of claim 1 to obtain a mosaic diamond;
implanting ions into the separated face of the separated mosaic diamond to form a non-diamond layer in the vicinity of the surface of the mosaic diamond;
growing a single-crystal diamond layer on the surface of the diamond by a vapor-phase synthesis method; and
etching the non-diamond layer to separate the single-crystal diamond layer formed in the portion above the non-diamond layer.

6. A process for producing a mosaic diamond by performing the following steps at least one time:
separating the single-crystal diamond layer formed in the portion above the non-diamond layers by any process of claim 2;
implanting ions into the single-crystal diamond substrates, from which the single-crystal diamond layer was separated, to form non-diamond layers in the vicinity of the surfaces of the single-crystal diamond substrates;
growing a single-crystal diamond layer on the surfaces of the substrates by a vapor-phase synthesis method; and
etching the non-diamond layers to separate the single-crystal diamond layer formed in the portion above the non-diamond layers.

7. A process for producing a mosaic diamond by performing the following steps at least one time:
separating the single-crystal diamond layer formed in the portion above the non-diamond layers by any process of claim 3;
implanting ions into the single-crystal diamond substrates, from which the single-crystal diamond layer was separated, to form non-diamond layers in the vicinity of the surfaces of the single-crystal diamond substrates;
growing a single-crystal diamond layer on the surfaces of the substrates by a vapor-phase synthesis method; and
etching the non-diamond layers to separate the single-crystal diamond layer formed in the portion above the non-diamond layers.

8. A process for producing a mosaic diamond by performing the following steps at least one time:
separating the single-crystal diamond layer formed in the portion above the non-diamond layers by any process of claim 2 to obtain a mosaic diamond;
implanting ions into the separated face of the separated mosaic diamond to form a non-diamond layer in the vicinity of the surface of the mosaic diamond;
growing a single-crystal diamond layer on the surface of the diamond by a vapor-phase synthesis method; and
etching the non-diamond layer to separate the single-crystal diamond layer formed in the portion above the non-diamond layer.

9. A process for producing a mosaic diamond by performing the following steps at least one time:
separating the single-crystal diamond layer formed in the portion above the non-diamond layers by any process of claim 3 to obtain a mosaic diamond;
implanting ions into the separated face of the separated mosaic diamond to form a non-diamond layer in the vicinity of the surface of the mosaic diamond;
growing a single-crystal diamond layer on the surface of the diamond by a vapor-phase synthesis method; and
etching the non-diamond layer to separate the single-crystal diamond layer formed in the portion above the non-diamond layer.
